(19) United States
(12) Patent Application Publication
(10) Pub. No.: US 2024/0141477 A1
(43) Pub. Date: May 2, 2024

(54) SPUTTERING TARGET AND METHOD FOR MANUFACTURING SAME

(71) Applicant: JX METALS CORPORATION, Tokyo (JP)

(72) Inventors: Hiroyoshi YAMAMOTO, Ibaraki (JP); Atsushi NARA, Ibaraki (JP)

(21) Appl. No.: 18/562,293

(22) PCT Filed: May 27, 2022
(86) PCT No.: PCT/JP2022/021801

§ 371 Date: Nov. 18, 2023

(30) Foreign Application Priority Data
Jun. 4, 2021 (JP) 2021-094549

(51) Int. Cl. C23C 14/34

(52) U.S. Cl. CPC C23C 14/3414

(57) ABSTRACT

An object of the present invention is to provide a sputtering target suitable for forming a semiconductor film having low carrier concentration and high mobility. Provided is a sputtering target containing zinc (Zn), tin (Sn), gallium (Ga) and oxygen (O), wherein the sputtering target contains Ga in an amount of 0.15 or more and 0.50 or less in terms of a Ga/(Zn+Sn+Ga) atomic ratio, contains Sn in an amount of 0.30 or more and 0.60 or less in terms of a Sn/(Zn+Sn) atomic ratio, and has a volume resistivity of 50 Ω·cm or less.

### TECHNICAL FIELD

The present invention relates to a sputtering target and a method for manufacturing the same.

### BACKGROUND ART

A Zn—Sn—O system (ZTO: Zinc-Tin-Oxide) is known as a material of transparent conductive films and semiconductor films. A transparent conductive film is used, for example, in solar batteries, liquid crystal surface devices, touch panels and the like (Patent Document 1 and so on). Moreover, a semiconductor film is used as a semiconductor layer (channel layer) of thin film transistors (TFT) (Patent Document 2 and so on). A ZTO film is normally deposited using a sputtering target made from a Zn—Sn—O-based sintered body.

A Ga—Zn—Sn—O-based (GZTO) film, in which the foregoing ZTO is doped with gallium (Ga), is also known. For example, Patent Documents 3 and 4 disclose the formation of a thin film using a sputtering target prepared from zinc oxide, gallium oxide, and tin oxide. The object of Patent Document 3 is to prepare a sputtering target having low bulk resistance and high density, and provide a transparent, amorphous semiconductor film in which selective etching to a metallic thin film is possible.

### PRIOR ART DOCUMENTS

### Patent Documents

[Patent Document 1] Japanese Unexamined Patent Application Publication No. 2017-36198
[Patent Document 2] Japanese Unexamined Patent Application Publication No. 2010-37161
[Patent Document 3] Japanese Unexamined Patent Application Publication No. 2010-18457
[Patent Document 4] Japanese Unexamined Patent Application Publication (Translation of PCT Application) No. 2016-507004

### DISCLOSURE OF THE INVENTION

### Problems to be Solved by the Invention

When a ZTO film is used as a semiconductor film, since the carrier concentration is high, there is a problem in that the power consumption is great. Thus, considered may be adjusting the composition of the film and lowering the carrier concentration. Nevertheless, when the carrier concentration is lowered, there was a problem in that the carrier mobility (hereinafter sometimes simply referred to as the “mobility”) will also consequently decrease, and the intended semiconductor properties could not be obtained. In light of the foregoing circumstances, an object of the present invention is to provide a sputtering target suitable for forming a semiconductor film having low carrier concentration and high mobility.

### Means for Solving the Problems

One mode of the present invention is a sputtering target containing zinc (Zn), tin (Sn), gallium (Ga) and oxygen (O), wherein the sputtering target contains Ga in an amount of 0.15 or more and 0.50 or less in terms of a Ga/(Zn+Sn+Ga) atomic ratio, contains Sn in an amount of 0.30 or more and 0.60 or less in terms of a Sn/(Zn+Sn) atomic ratio, and has a volume resistivity of 50 Ω·cm or less.

### Effect of the Invention

According to the present invention, it is possible to yield a superior effect of being able to provide a sputtering target suitable for forming a semiconductor film having low carrier concentration and high mobility.

### BEST MODE FOR CARRYING OUT THE INVENTION

### [Semiconductor Film]

In a semiconductor film, the carrier concentration and mobility are of a positive correlation, and higher the carrier concentration, higher the mobility. Thus, considered may be increasing the carrier concentration to increase the mobility, but when the carrier concentration is increased, there is a problem in that the power consumption will also increase. In recent years, the problem of power consumption has become notable pursuant to the miniaturization of semiconductor devices, and there are demands for reducing the power consumption, but since the mobility and power consumption are of a trade-off relationship, it is necessary to obtain a carrier concentration capable of satisfying both the mobility and the power consumption.

As a result of intense study by the present inventors concerning the foregoing problem, the present inventors discovered that low carrier concentration and high mobility can be achieved with a semiconductor film (hereinafter sometimes hereinafter simply referred to as the “film”) containing zinc (Zn), tin (Sn), gallium (Ga) and oxygen (O), and which satisfies formula (1) and formula (2) below.

0.15≤Ga/(Zn+Sn+Ga)≤0.50 (1)

0.33≤Sn/(Zn+Sn)≤0.65 (2)

(in the formulas, Ga, Zn and Sn each indicate the atomic ratio of each element in the film)

When the Ga content in the film is less than 0.15 in terms of a Ga/(Zn+Sn+Ga) atomic ratio, the intended carrier concentration becomes excessively high, and the power consumption will increase more than expected. Meanwhile, when the Ga content in the film exceeds 0.50 in terms of a Ga/(Zn+Sn+Ga) atomic ratio, the intended mobility cannot be obtained. The Ga content in the film is preferably 0.15 or more and 0.40 or less in terms of a Ga/(Zn+Sn+Ga) atomic ratio, and more preferably 0.15 or more and 0.25 or less in terms of a Ga/(Zn+Sn+Ga) atomic ratio.

When the Sn content in the film is less than 0.33 in terms of a Sn/(Sn+Zn) atomic ratio, there is a problem in that the variation rate of the film properties (carrier concentration, mobility, volume resistivity) due to heat will increase when the film is annealed. Meanwhile, when the Sn content in the film exceeds 0.65 in terms of a Sn/(Sn+Zn) atomic ratio, the carrier concentration becomes excessively high, and the power consumption will increase more than expected. The Sn content in the film is preferably 0.33 or more and 0.60 or less in terms of a Sn/(Sn+Zn) atomic ratio, and more preferably 0.33 or more and 0.50 or less in terms of a Sn/(Sn+Zn) atomic ratio.

The carrier concentration of a semiconductor film is preferably 1.0×10¹⁷ cm⁻³ or less, more preferably 1.0×10¹⁶ cm⁻³ or less, and most preferably 1.0×10¹⁵ cm⁻³ or less. When the carrier concentration is within the foregoing range, the power consumption can be sufficiently reduced.

The mobility of a semiconductor film is preferably 5.0 cm²/V·s or more, more preferably 10.0 cm²/V·s or more, and most preferably 12.0 cm²/V·s or more. When the mobility is within the foregoing range, the intended semiconductor properties can be obtained.

Moreover, with a semiconductor film, the refractive index of light having a wavelength of 405 nm is preferably 2.15 or less, and more preferably 2.10 or less and 2.00 or more. By causing the refractive index to fall within the foregoing numerical range, the effect of being able to prevent the scattering caused by the mediums can be obtained.

Moreover, with a semiconductor film, the extinction coefficient of light having a wavelength of 405 nm is preferably 0.02 or less, and more preferably 0.01 or less. By causing the extinction coefficient to fall within the foregoing numerical range, the effect of being able to attain high transparency can be obtained.

### [Sputtering Target]

With the sputtering method, since deposition is performed in a vacuum, under normal circumstances, the composition of the sputtering target (atomic ratio of metal components) is reflected in the composition of the film without any partial loss of the metal components configuring the sputtering target or any inclusion of other metal components during the deposition process. Nevertheless, with a GZTO sputtering target, since the sputter rate will differ depending on the structural components and crystal phase of the metals, the composition of the film will vary (this is hereinafter sometimes referred to as the “composition variation of the film”). Particularly, the ratio of tin (Sn) of the film will increase relative to the sputtering target.

As a result of intense study by the present inventors concerning the composition variation of the film, the present inventors discovered that the foregoing intended semiconductor film can be deposited based on DC sputtering by adjusting the composition range of the sputtering target and devising the manufacturing method thereof. In light of the foregoing discovery, this embodiment is a sputtering target containing zinc (Zn), tin (Sn), gallium (Ga) and oxygen (O), which satisfies formula (3) and formula (4) below, and in which the volume resistivity is 50 Ω·cm or less.

0.15≤Ga/(Zn+Sn+Ga)≤0.50 (3)

0.30≤Sn/(Zn+Sn)≤0.60 (4)

(in the formulas, Ga, Zn and Sn each indicate the atomic ratio of each element in the film)

The Ga content in the sputtering target is 0.15 or more and 0.50 or less in terms of a Ga/(Zn+Sn+Ga) atomic ratio, preferably 0.15 or more and 0.40 or less in terms of a Ga/(Zn+Sn+Ga) atomic ratio, and more preferably 0.15 or more and 0.25 or less in terms of a Ga/(Zn+Sn+Ga) atomic ratio.

In the sputtering target, the Sn content is 0.30 or more and 0.60 or less in terms of a Sn/(Zn+Sn) atomic ratio, preferably 0.30 or more and 0.50 or less in terms of a Sn/(Sn+Zn) atomic ratio, and more preferably 0.33 or more and 0.45 or less in terms of a Sn/(Sn+Zn) atomic ratio.

When the composition of the sputtering target is within the foregoing numerical range, a semiconductor film having the intended composition can be deposited.

While the sputtering target according to this embodiment has a volume resistivity of 50 Ω·cm or less, the volume resistivity is preferably 30 Ω·cm or less, and more preferably 10 Ω·cm or less. When the volume resistivity of the sputtering target is low, deposition can be performed stably during DC sputtering. In this disclosure, the volume resistivity was measured in the following manner.

Measuring device: Resistivity meter E-5+

Measurement system: Constant current application system

Measurement method: DC four probe method

The volume resistivity was measured at one location at the center and four locations at 90-degree intervals near the outer periphery on the surface of the sputtering target, and the average value thereof was obtained.

With the sputtering target according to this embodiment, the relative density is preferably 97% or higher, more preferably 98% or higher, and most preferably 99% or higher. A high density sputtering target can reduce the amount of particles that are generated during deposition.

The relative density is calculated based on the following formula.

Relative density (%)=(measured density)/(standard density)×100

The standard density is the value of density calculated from the theoretical density and mass ratio of the oxides of elements excluding oxygen in the respective constituent elements of the sputtering target, and the theoretical density of each oxide is as follows.

Theoretical density of Ga₂O₃: 5.95 g/cm³

Theoretical density of SnO: 6.95 g/cm³

Theoretical density of ZnO: 5.61 g/cm³

The measured density is the value obtained by dividing the weight of the sputtering target by its volume, and is calculated using the Archimedes method.

With the sputtering target according to this embodiment, the average crystal grain size is preferably 10 μm or less, and more preferably 5 μm or less. When the texture of the sputtering target is fine, the amount of particles that are generated during deposition can be reduced.

### [Manufacturing Method of Sputtering Target]

The sputtering target according to this embodiment can be manufactured, for example, in the following manner. Nevertheless, the following manufacturing method is merely illustrative, and it should be understood that this embodiment is not limited to this manufacturing method. Moreover, the detailed explanation of known processes is omitted to avoid the manufacturing method from becoming unnecessarily unclear.

### (Mixing and Pulverization of Raw Materials)

As raw materials, a ZnO powder, a SnO powder and a Ga₂O₃ powder are prepared, and these raw materials are weighed and mixed to obtain the intended compound ratio. The raw materials are pulverized as needed, and the resulting average grain size (D50) is preferably 1.5 μm or less.

### (Calcination of Mixed Powder)

The obtained mixed powder is calcined at 1000° C. to 1300° C. for 4 to 7 hours. As a result of performing calcination, a compound oxide (Zn₂SnO₄ phase, ZnGa₂O₄ phase) can be obtained.

### (Hot Press Sintering)

The mixed powder or the calcined powder is filled in a carbon mold, and subject to pressure sintering (hot press) in a vacuum or inert gas atmosphere. The hot press conditions are preferably set as follows; namely, sintering temperature of 950° C. to 1100° C., applied pressure of 200 to 300 kgf/cm², and holding time of 1 to 4 hours. This is because, when the sintering temperature is too low, a high density sintered body cannot be obtained, and when the sintering temperature is too high, compositional variation caused by the evaporation of ZnO will occur. Note that, when sintering is performed in the atmosphere without applying pressure (atmospheric pressureless sintering), the volume resistivity of the sintered body will increase or the density of the sintered body will decrease. Thus, it is necessary to perform hot press sintering in order to obtain the intended sputtering target.

### (Surface Finishing)

By preparing a sintered body based on the foregoing processes and subsequently subjecting the sintered body to machining processes such as cutting and grinding, a sputtering target can be manufactured.

### EXAMPLES

The present invention is now explained based on the following Examples and Comparative Examples. Note that the following Examples are merely representative examples, and the present invention is not limited to these Examples in any way. In other words, the present invention is limited only based on the scope of its claims, and covers various modifications other than the Examples included in the present invention.

The deposition conditions using a sputtering target were set as follows. Moreover, the sputtering targets and the films were evaluated in the following manner.

### (Deposition Conditions)

Deposition principle: DC sputtering

Deposition device: ANELVASPL-500

Size of sputtering target: Diameter 6 inches, thickness 5 mm

Substrate: Glass

Film thickness: 60 to 900 nm

Power: 2.74 to 5.48 W/cm²

Atmosphere: Ar+2% O₂, 0.5 Pa, 28 to 50 sccm

### (Composition of Sputtering Target)

Method: ICP-OES (Inductively Coupled Plasma Optical Emission Spectrometry)

Device: SPS3500DD manufactured by SII

### (Crystal Grain Size of Sputtering Target)

The surface that is parallel to the surface of the sputtering target to be sputtered was observed using a scanning electron microscope (SEM), and the crystal grain size was obtained by performing evaluation based on the cutting method of JISG0551.

### (Composition of Film)

Measuring principle: FE-EPMA quantitative analysis

Measuring device: JXA-8500F manufactured by JEOL

Measurement condition: Acceleration voltage 15 kV

Illumination current 2×10⁷ A

Beam diameter 100 μm

### (Carrier Concentration of Film)

Measuring principle: Hall measurement

Measuring device: 8400 model manufactured by LakeShore

Measurement condition: Sample was measured after being annealed at 200° C.

### (Mobility of Film)

Measuring principle: Hall measurement

Measuring device: 8400 model manufactured by LakeShore

Measurement condition: Sample was measured after being annealed at 200° C.

### Example 1

A ZnO powder, a SnO powder and a Ga₂O₃ powder were prepared, these raw materials were blended to achieve the composition ratio of the sputtering target indicated in Table 1, and thereafter mixed. Next, the mixed powder was pulverized via wet pulverization (ZrO₂ beads were used) to achieve an average grain size of 1.5 μm or less, dried, and thereafter sieved using a sieve having a sieve opening of 500 μm. Next, the pulverized powder was filled in a carbon mold, hot pressed in an argon atmosphere under the following conditions; namely, sintering temperature of 950° C., applied pressure of 250 kgf/cm², and sintering time of 2 hours, and the thus obtained oxide sintered body was machined to obtain a shape of a sputtering target (diameter of 6 inches).

The relative density, average crystal grain size and volume resistivity of the Zn—Sn—Ga—O sputtering target prepared above were measured. The results are shown in Table 1. As a result of performing DC sputtering using this sputtering target, arcing did not occur during sputtering, and it was possible to perform sputtering stably.

### Examples 2 to 8

As with Example 1, a ZnO powder, a SnO powder and a Ga₂O₃ powder were prepared, these raw materials were blended to achieve the composition ratio of the sputtering target indicated in Table 1, and thereafter mixed. Next, the mixed powder was pulverized via wet pulverization (ZrO₂ beads were used) to achieve an average grain size of 1.5 μm or less, dried, and thereafter sieved using a sieve having a sieve opening of 500 μm. Next, the pulverized powder was filled in a carbon mold, hot pressed in an argon atmosphere under the following conditions; namely, sintering temperature of 950° C., 1020° C. and 1050° C., applied pressure of 250 kgf/cm², and sintering time of 2 hours, and the thus obtained sintered body was machined to obtain a shape of a sputtering target (diameter of 6 inches). The results of analyzing the relative density, average crystal grain size and volume resistivity of the obtained sputtering targets are shown in Table 1. Note that Examples 2 to 7 were prepared to examining the properties of the sputtering targets, and deposition was not performed using these sputtering targets.

### Comparative Examples 1 to 6

As with Example 1, a ZnO powder, a SnO powder and a Ga₂O₃ powder were prepared, these raw materials were blended to achieve the composition ratio of the sputtering target indicated in Table 1, and thereafter mixed. Note that the Ga₂O₃ powder was not mixed in Comparative Examples 1 to 4.

Next, the mixed powder was pulverized via wet pulverization (ZrO₂ beads were used) to achieve an average grain size of 1.5 μm or less, dried, and thereafter sieved using a sieve having a sieve opening of 500 μm. Next, the pulverized powder was filled in a carbon mold and sintered under the conditions described in Table 1, and the thus obtained sintered body was machined to obtain a shape of a sputtering target (diameter of 6 inches). Note that hot press sintering was performed in Comparative Examples 1 to 4, and pressureless sintering was performed in Comparative Examples 5 and 6 in the atmosphere under the following conditions; namely, sintering temperature of 1400° C. and sintering time of 2 hours. The results of analyzing the relative density, average crystal grain size and volume resistivity of the obtained sputtering targets are shown in Table 1. Note that, since the volume resistivity of Comparative Examples 5 and 6 is high, it can be assumed that it is not possible to perform DC sputtering using these sputtering targets.

TABLE 1

| | Imposition of sputtering | | | | | | | | | | | | |
|---|---|---|---|---|---|---|---|---|---|---|---|---|---|
| | target [metal atom %] | | | | | | Sintering conditions | | | | | | |
| | preparation (measured val) | | | | | | | Applied | | Aver- | Mea- | Theo- | Rel- |
| | | | | Ga/ | Sn/ | | | press- | Volume | age | sured | retical | ative |
| | | | | (Ga + | (Ga + | Sn/ | Sintering | ure | resis- | grain | den- | den- | den- |
| | | | | Zn + | Zn + | (Zn + | temperature, | (kg/ | tivity | size | sity | sity | sity |
| | Ga | Zn | Sn | Sn) | Sn) | Sn) | atmosphere | cm³) | [Ω · cm] | [μm] | [g/cm³] | [g/cm³] | [%] |
| Example 1 | 15.0 | 56.4 | 28.6 | 0.15 | 0.29 | 0.34 | 1050° C., argon | 250 | 5.2 | 4.8 | 6.23 | 6.15 | 101.3 |
| Example 2 | 20.0 | 32.6 | 47.4 | 0.20 | 0.47 | 0.59 | 1050° C., argon | 250 | 2.5 | 1.5 | 6.31 | 6.43 | 98.3 |
| Example 3 | 30.0 | 28.5 | 41.6 | 0.30 | 0.42 | 0.59 | 1050° C., argon | 250 | 1.4 | 1.4 | 6.30 | 6.38 | 98.8 |
| Exemple 4 | 40.0 | 40.0 | 20.0 | 0.40 | 0.20 | 0.33 | 1050° C., argon | 250 | 26.0 | 2.0 | 5.93 | 6.09 | 97.4 |
| Example 5 | 50.0 | 30.0 | 20.0 | 0.50 | 0.20 | 0.40 | 1050° C., argon | 250 | 10.6 | 1.7 | 6.03 | 6.12 | 98.6 |
| Example 6 | 25.0 | 30.0 | 45.0 | 0.25 | 0.45 | 0.60 | 1050° C., ergon | 250 | 1.4 | 2.3 | 6.26 | 6.41 | 97.7 |
| Example 7 | 25.0 | 30.0 | 45.0 | 0.25 | 0.45 | 0.60 | 950° C., argon | 250 | 1.1 | 1.9 | 6.36 | 6.41 | 99.2 |
| Example 8 | 23.0 | 46.0 | 31.0 | 0.23 | 0.31 | 0.40 | 1050° C., argon | 250 | 16.4 | 2.6 | 6.26 | 6.21 | 100.6 |
| Comparative Example 1 | 0.0 | 40.0 | 60.0 | 0.00 | 0.80 | 0.60 | 1060° C., argon | 250 | — | — | 5.9 | 6.54 | 90.1 |
| Comparative Example 2 | 0.0 | 50.0 | 50.0 | 0.00 | 0.50 | 0.50 | 1050° C., argon | 250 | — | — | 5.9 | 6.41 | 92.6 |
| Comparative Example 3 | 0.0 | 60.0 | 40.0 | 0.00 | 0.40 | 0.40 | 1050° C., argon | 250 | 0.1 | — | 6.0 | 6.28 | 95.4 |
| Comparative Example 4 | 0.0 | 67.0 | 33.0 | 0.00 | 0.33 | 0.33 | 1050° C., argon | 250 | 0.1 | 18.1 | 6.4 | 6.183 | 102.8 |
| Comparative Example 5 | 40.0 | 40.0 | 20.0 | 0.40 | 0.20 | 0.33 | 1400° C., air | — | ≥500 kΩ | 4.2 | 5.15 | 6.09 | 84.6 |
| Comparative Example 6 | 50.0 | 30.0 | 20.0 | 0.50 | 0.20 | 0.40 | 1400° C., air | — | ≥500 kΩ | 4.1 | 5.39 | 6.12 | 88.1 |

### [Evaluation of Semiconductor Thin Film]

The sputtering targets prepared in Examples 1 and 8 were respectively mounted on a sputtering device, and a film was deposited by performing sputtering under the foregoing conditions. As Deposition Examples 1 and 2, the compositions of the films are shown in Table 2. The carrier concentration, mobility, refractive index, and extinction coefficient were analyzed for each Deposition Example. As a result, the carrier concentration was 1.0×10¹⁷ cm⁻³ or less in both cases and the mobility was 5.0 cm²/V·s or more in both cases, and the intended results were obtained. Moreover, the refractive index was 2.15 or less in both cases and the extinction coefficient was 0.02 or less in both cases, and favorable results were obtained. These results are shown in Table 2.

The sputtering targets prepared in Comparative Examples 1 to 4 were respectively mounted on a sputtering device, and a film was deposited by performing sputtering under the foregoing conditions. As Deposition Examples 12 to 15, the compositions of the films are shown in Table 2. The carrier concentration, mobility, refractive index, and extinction coefficient were analyzed for each Deposition Example. As a result, the carrier concentration exceeded 1.0×10¹⁷ cm⁻³ in all cases. Accordingly, it is expected that the power consumption will increase if this kind of film is used as a semiconductor film. Otherwise, the analytical results of the mobility, refractive index and extinction coefficient are shown in Table 2.

In order to analyze the relationship of the composition of the film and the carrier concentration and mobility in detail, films having different compositions were deposited based on simultaneous sputtering (co-sputtering), and the carrier concentration, mobility and so on of each film were measured. For the co-sputtering, a ZnSnO sputtering target and a Ga₂O₃ sputtering target were used, and the Ga concentration in the film was adjusted by changing the sputtering power, and the concentration of Zn and Sn in the film was adjusted by using four types of ZnSnO sputtering rings with different compositions. The compositions of the four types of ZnSnO sputtering rings indicated above were Zn:Sn=66.7 at %:33.3 at %, 60.0 at %:40.0 at %, 50.0 at %:50.0 at %, and 40 at %:60 at %.

The compositions of the films of Deposition Examples 3 to 11 and Deposition Examples 16 to 19 based on the foregoing co-sputtering are shown in Table 2. Moreover, the carrier concentration, mobility, refractive index, and extinction coefficient of each of the obtained films were analyzed. With Deposition Examples 3 to 11 that satisfy (1) 0.15≤Ga/(Zn+Sn+Ga)≤0.50, (2) 0.33≤Sn/(Zn+Sn)≤0.65, the carrier concentration was 1.0×10¹⁷ cm⁻³ or less and the mobility was 5.0 cm²/V·s or more, and the intended results were obtained. Meanwhile, with Deposition Example 16 that fails to satisfy foregoing formula (1), the intended carrier concentration could not be obtained, and with Deposition Examples 17 to 19 that fail to satisfy foregoing formula (2), the intended mobility could not be obtained.

TABLE 2

| | | Composition of oxide film | | | | | | | | | |
|---|---|---|---|---|---|---|---|---|---|---|---|
| | | [metal atom %] measured value | | | | | | | | | Extinc- |
| | | | | | Ga/ | Sn/ | | Carrier | Mobil- | Refrac- | tion |
| | | | | | (Ga + | (Ga + | Sn/ | concen- | ity | tive | coeffi- |
| | Sputtering | | | | Zn + | Zn + | (Zn + | tration | [cm²/ | index | cient |
| | target | Ga | Zn | Sn | Sn) | Sn) | Sn) | [1/cm3] | V · s] | [—] | [—] |
| Deposition Example 1 | Example 1 | 17 | 50 | 33 | 0.17 | 0.33 | 0.40 | 1.2E+16 | 9.4 | 2.12 | 0.005 |
| Deposition Example 2 | Example 8 | 25 | 37 | 37 | 0.25 | 0.37 | 0.50 | 1.3E+15 | 7.3 | 2.07 | 0.018 |
| Deposition Example 3 | Co-sputtering | 20 | 35 | 46 | 0.20 | 0.46 | 0.57 | 4.2E+16 | 9.7 | 2.10 | 0.012 |
| Deposition Example 4 | Co-sputtering | 26 | 32 | 42 | 0.26 | 0.42 | 0.57 | 9.5E+14 | 8.2 | 2.06 | 0.004 |
| Deposition Example 5 | Co-sputtering | 31 | 26 | 43 | 0.31 | 0.43 | 0.62 | 3.0E+14 | 6.3 | 2.03 | 0.003 |
| Deposition Example 6 | Co-sputtering | 23 | 40 | 37 | 0.23 | 0.37 | 0.48 | 4.5E+15 | 11.3 | 2.09 | 0.011 |
| Daposition Example 7 | Co-sputtering | 31 | 36 | 34 | 0.31 | 0.34 | 0.49 | 8.5E+14 | 8.8 | 2.08 | 0.014 |
| Deposition Exemple 8 | Co-sputtering | 38 | 31 | 31 | 0.38 | 0.31 | 0.50 | 9.8E+13 | 7.1 | 2.05 | 0.013 |
| Deposition Example 9 | Co-sputtering | 50 | 24 | 26 | 0.50 | 0.26 | 0.52 | 1.0E+13 | 5.2 | 2.02 | 0.008 |
| Deposition Example 10 | Co-sputtering | 24 | 45 | 31 | 0.24 | 0.31 | 0.41 | 2.4E+14 | 12.8 | 2.08 | 0.003 |
| Deposition Example 11 | Co-sputtering | 38 | 36 | 27 | 0.38 | 0.27 | 0.43 | 3.8E+13 | 10.5 | 2.05 | 0.004 |
| Deposition Example 12 | Comparative Example 1 | 0 | 30 | 70 | 0.00 | 0.70 | 0.70 | 1.6E+19 | 7.2 | 2.18 | 0.052 |
| Deposition Example 13 | Comparative Example 2 | 0 | 43 | 57 | 0.00 | 0.57 | 0.57 | 1.1E+19 | 14.0 | 2.11 | 0.028 |
| Deposition Example 14 | Comparative Example 3 | 0 | 54 | 46 | 0.00 | 0.46 | 0.46 | 5.5E+18 | 19.7 | 2.12 | 0.020 |
| Deposition Example 15 | Comparative Example 4 | 0 | 61 | 39 | 0.00 | 0.39 | 0.39 | 7.9E+17 | 18.2 | 2.06 | 0.012 |
| Deposition Example 16 | Co-sputtering | 10 | 36 | 54 | 0.10 | 0.54 | 0.60 | 6.3E+17 | 9.1 | — | — |
| Deposition Example 17 | Co-sputtering | 28 | 22 | 51 | 0.28 | 0.51 | 0.70 | 5.8E+15 | 4.8 | 2.11 | 0.036 |
| Deposition Example 18 | Co-sputtering | 35 | 19 | 46 | 0.35 | 0.46 | 0.71 | 8.1E+14 | 4.0 | 2.09 | 0.033 |
| Deposition Example 19 | Co-sputtering | 46 | 16 | 39 | 0.46 | 0.39 | 0.71 | 5.1E+13 | 3.9 | 2.06 | 0.023 |

### INDUSTRIAL APPLICABILITY

According to the present invention, it is possible to yield a superior effect of being able to provide a sputtering target suitable for forming a semiconductor film having low carrier concentration and high mobility. The semiconductor film obtained with the present invention is useful as a transparent conductive film of solar batteries, liquid crystal surface devices and touch panels, and as a semiconductor film for use as a TFT channel layer.

1: A sputtering target containing zinc (Zn), tin (Sn), gallium (Ga) and oxygen (O), wherein the sputtering target contains Ga in an amount of 0.15 or more and 0.25 or less in terms of a Ga/(Zn+Sn+Ga) atomic ratio, contains Sn in an amount of 0.30 or more and 0.60 or less in terms of a Sn/(Zn+Sn) atomic ratio, and has a volume resistivity of 50 Ω·cm or less.

2: The sputtering target according to claim 1, wherein the sputtering target has a relative density of 97% or higher.

3: The sputtering target according to claim 2, wherein the sputtering target has an average crystal grain size of 10 μm or less.

4: A method of manufacturing the sputtering target according to claim 3, wherein a ZnO powder, a SnO₂ powder and a Ga₂O₃ powder are weighed and mixed, and thereafter subject to hot press sintering.

5: The method of manufacturing the sputtering target according to claim 4, wherein the mixed powder is calcined at 1000° C. to 1300° C., and the calcined powder is subject to hot press sintering.

6: A method of manufacturing the sputtering target according to claim 2, wherein a ZnO powder, a SnO₂ powder and a Ga₂O₃ powder are weighed and mixed, and thereafter subject to hot press sintering.

7: The method of manufacturing the sputtering target according to claim 6, wherein the mixed powder is calcined at 1000° C. to 1300° C., and the calcined powder is subject to hot press sintering.

8: The sputtering target according to claim 1, wherein the sputtering target has an average crystal grain size of 10 μm or less.

9: A method of manufacturing the sputtering target according to claim 8, wherein a ZnO powder, a SnO₂ powder and a Ga₂O₃ powder are weighed and mixed, and thereafter subject to hot press sintering.

10: The method of manufacturing the sputtering target according to claim 9, wherein the mixed powder is calcined at 1000° C. to 1300° C., and the calcined powder is subject to hot press sintering.

11: A method of manufacturing the sputtering target according to claim 1, wherein a ZnO powder, a SnO₂ powder and a Ga₂O₃ powder are weighed and mixed, and thereafter subject to hot press sintering.

12: The method of manufacturing the sputtering target according to claim 11, wherein the mixed powder is calcined at 1000° C. to 1300° C., and the calcined powder is subject to hot press sintering.
